(19) United States
(12) Patent Application Publication
(10) Pub. No.: US 2025/0286312 A1
(43) Pub. Date: Sep. 11, 2025

(54) CONNECTOR UNIT

(71) Applicant: YAZAKI CORPORATION, Tokyo (JP)

(72) Inventors: Kei Fujimoto, Makinohara-shi (JP); Takashi Muro, Makinohara-shi (JP)

(21) Appl. No.: 19/051,186

(22) Filed: Feb. 12, 2025

(30) Foreign Application Priority Data
Mar. 8, 2024 (JP) 2024-036052

(51) Int. Cl. H01R 13/533; H01R 13/502; H01R 24/66; H05K 7/20

(52) U.S. Cl. CPC H01R 13/533; H01R 13/502; H01R 24/66; H05K 7/2039

(57) ABSTRACT

A connector unit includes: a terminal fitting; a housing configured to accommodate the terminal fitting; a fixing fitting embedded in the housing and configured to fasten and fix the terminal fitting and an external conductive component; a metal frame member on which the housing is mounted; and a heat transfer member configured to thermally connect the frame member and a part of the fixing fitting exposed from the housing. The heat transfer member is sandwiched between the part of the fixing fitting and the frame member, and is flexible enough to deform to fit a shape of a gap between the part of the fixing fitting and the frame member.

### CROSS-REFERENCE TO RELATED APPLICATION(S)

This application is based upon and claims the benefit of priority from prior Japanese patent application No. 2024-036052 filed on Mar. 8, 2024, the entire contents of which are incorporated herein by reference.

### BACKGROUND

### 1. Field of the Invention

The present disclosure relates to a connector unit including a terminal fitting, a housing that houses the terminal fitting, a fixing fitting that is embedded in the housing and that fastens and fixes the terminal fitting and an external conductive component, a metal frame member to which the housing is attached, and a heat transfer member that thermally connects the frame member and a part of the fixing fitting exposed from the housing.

### 2. Description of the Related Art

In the related art, various connectors have been proposed for use in a power cable for supplying power from a power source mounted on a vehicle or the like to an electrical load (for example, see JP2022-83460A).

In the above-described types of connectors, a terminal fitting and conductive components such as an electric wire and a bus bar are generally electrically connected in a housing. Although the connection portion between the terminal fitting and these conductive components is a portion where a large amount of Joule heat is generated at the time of energization due to the large contact resistance, the connection portion is isolated from the outside by being covered with the housing. Therefore, it is difficult to dissipate heat from the connection portion to the outside. Due to such difficulties in dissipating heat, the temperature of the connector may rise excessively at the time of energization, which may cause deterioration of the components that constitute the connector. On the other hand, simply attaching a dedicated heat dissipation member (for example, a heat dissipation fin) to the outside of the connector is undesirable because the heat dissipation member may hinder the miniaturization of the connector and because the space for providing the connector inside the vehicle body is limited.

### SUMMARY

An object of the present disclosure is to provide a connector unit capable of improving the heat dissipation property while avoiding an increase in size of the connector unit.

In order to achieve the above object, a connector unit according to the present disclosure has the following features.

According to an aspect of the present disclosure, there is provided a connector unit including: a terminal fitting; a housing configured to accommodate the terminal fitting; a fixing fitting embedded in the housing and configured to fasten and fix the terminal fitting and an external conductive component; a metal frame member on which the housing is mounted; and a heat transfer member configured to thermally connect the frame member and a part of the fixing fitting exposed from the housing, in which the heat transfer member is sandwiched between the part of the fixing fitting and the frame member, and is flexible enough to deform to fit a shape of a gap between the part of the fixing fitting and the frame member.

According to the connector unit in the present disclosure, the external conductive component (for example, a round terminal and a bus bar) and the terminal fitting are fixed to the housing in a state of being fastened and fixed to the fixing fitting embedded in the housing and being electrically connected. Further, the heat transfer member is sandwiched between the part of the fixing fitting exposed from the housing and the metal frame member. Accordingly, the heat generated at the contact point between the terminal fitting and the counterpart terminal fitting, the connection location between the terminal fitting and the conductive component, and the like at the time of energization is transferred in the order of the fixing fitting, the heat transfer member, and the frame member. The heat transfer member is flexible enough to deform to fit the shape of the gap between the frame member and the part of the fixing fitting, and thus comes into contact with both the frame member and the part of the fixing fitting with a larger contact area as compared with the case in which the heat transfer member does not have such flexibility. Further, even when an external force such as vibration is applied when the connector unit is used, or even when the connector unit is used for a long period of time, a state can be maintained in which the heat transfer member is in contact with the frame member and the part of the fixing fitting. In addition, the metal frame member has a large heat capacity and high thermal conductivity, and since the frame member is in contact with the outside air, the frame member also has excellent heat dissipation property. Accordingly, the connector unit having the present configuration can improve the heat dissipation property while avoiding an increase in size of the connector unit.

The heat transfer member may be in direct contact with the frame member and the part of the fixing fitting, or indirectly in contact with the frame member and the part of the fixing fitting with an adhesive, a pressure-sensitive adhesive, or the like interposed therebetween. However, in the latter case, it is preferable that the adhesive, the pressure-sensitive adhesive, or the like also has high thermal conductivity. Further, in addition to the adhesive, the pressure-sensitive adhesive, or the like, the heat transfer member may be indirectly in contact with the frame member and the part of the fixing fitting with another member that has high thermal conductivity or the like interposed therebetween.

The present disclosure has been briefly described above. Further, details of the present disclosure will be clarified by reading modes for carrying out the invention to be described below with reference to the accompanying drawings.

### BRIEF DESCRIPTION OF THE DRAWINGS

The present disclosure will become more fully understood from the detailed description given hereinbelow and the accompanying drawing which is given by way of illustration only, and thus is not limitative of the present disclosure and wherein:

FIG. 1 is a perspective view showing a connector unit and a counterpart connector according to an embodiment of the present disclosure;

FIG. 2 is a perspective view of the connector unit shown in FIG. 1;

FIG. 3 is a perspective view showing a state in which a housing, a frame member, and a heat transfer member constituting the connector unit shown in FIG. 2 are separated from one another;

FIG. 4 is a cross-sectional view taken along a line A-A in FIG. 2; and

FIG. 5 is an enlarged view of a portion B in FIG. 4.

### DETAILED DESCRIPTION OF THE INVENTION

### Embodiment

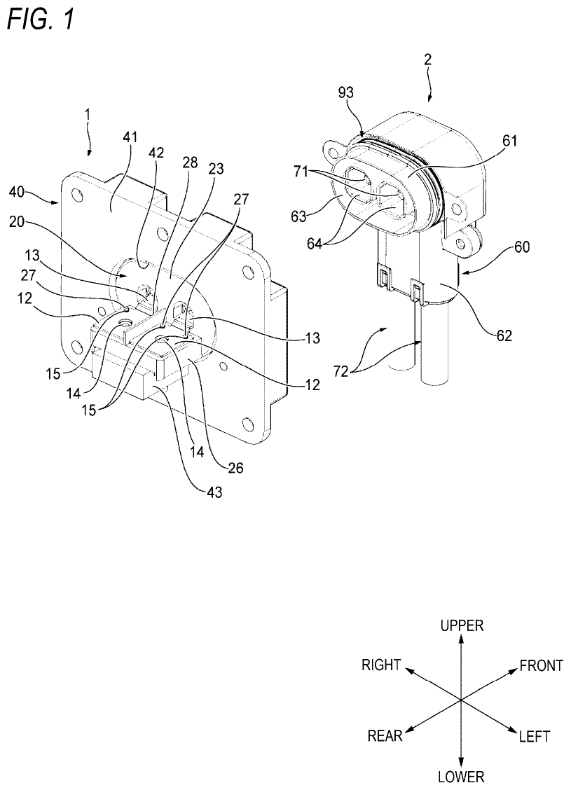

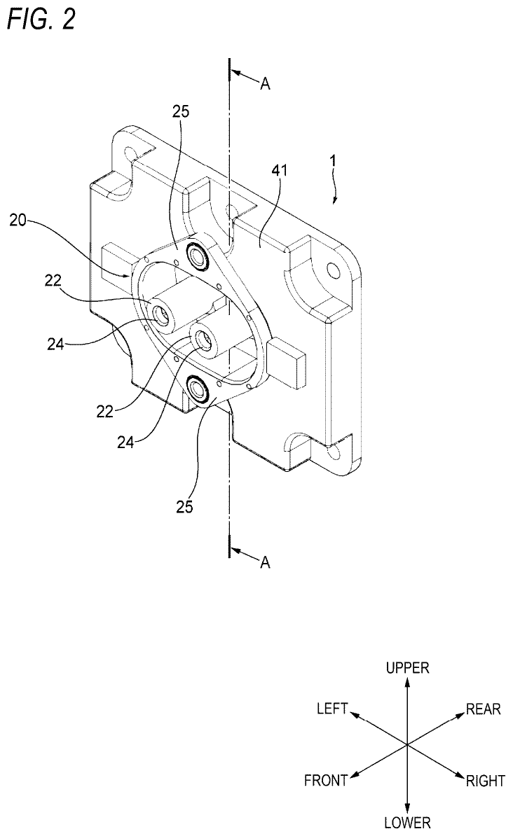

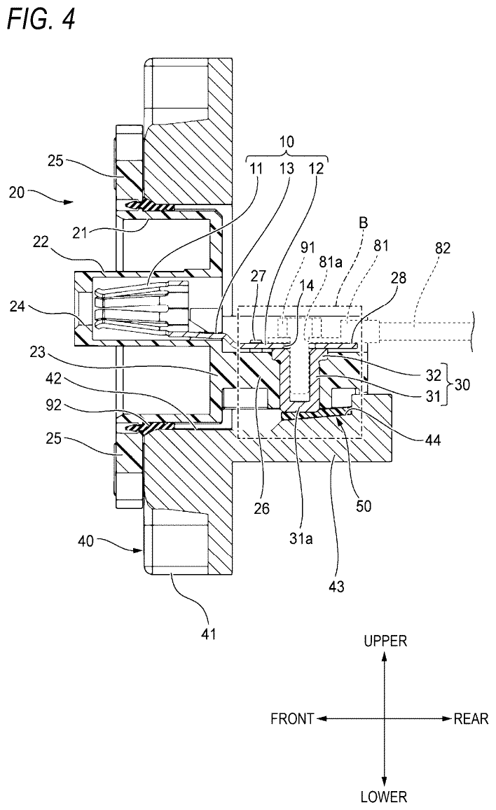

Hereinafter, a connector unit 1 according to an embodiment of the present disclosure will be described with reference to the drawings. The connector unit 1 shown in FIGS. 1 and 2 functions as a relay connector that electrically connects an electric wire 82 (see FIG. 4) extending from a housing 20 of the connector unit 1 and a counterpart connector 2 (see FIG. 1) fitted in the connector unit 1.

Hereinafter, for convenience of description, “front”, “rear”, “upper”, “lower”, “left”, “right”, a “front-rear direction”, an “upper-lower direction”, and a “left-right direction” are defined as shown in FIG. 1. The “front-rear direction”, the “upper-lower direction”, and the “left-right direction” are orthogonal to one another. The front-rear direction coincides with the fitting direction of the connector unit 1 and the counterpart connector 2.

As shown in FIGS. 1 to 4, the connector unit 1 mainly includes a terminal fitting 10, the housing 20, a nut member 30, a frame member 40, and a heat transfer member 50. Hereinafter, the configurations of the members that constitute the connector unit 1 will be described in order.

First, the terminal fitting 10 will be described. As shown in FIG. 4, the metal terminal fitting (the female terminal) 10 integrally includes a tubular contact portion 11, a plate-shaped fastening portion 12 that is located on the rear side of the tubular contact portion 11, and a plate-shaped connecting portion 13 that connects the tubular contact portion 11 and the plate-shaped fastening portion 12. The tubular contact portion 11 is a portion that is electrically connected to a terminal fitting (a male terminal) 71 (see FIG. 1) on the counterpart connector 2 side when the connector unit 1 and the counterpart connector 2 are fitted to each other, and has a tubular shape that extends in the front-rear direction. The plate-shaped fastening portion 12 is a portion to which an external terminal 81 connected to the electric wire 82 is fastened and fixed using the nut member 30 and a bolt 91, and has a substantially rectangular flat plate shape whose plate thickness direction is oriented in the upper-lower direction (see also FIG. 1). A bolt through hole 14 is formed in the central portion of the plate-shaped fastening portion 12, penetrating the plate-shaped fastening portion 12 in the plate thickness direction (the upper-lower direction). A pair of left and right locking holes (penetrating holes) 15 are formed in the front end portion of the plate-shaped fastening portion 12 (see FIG. 1).

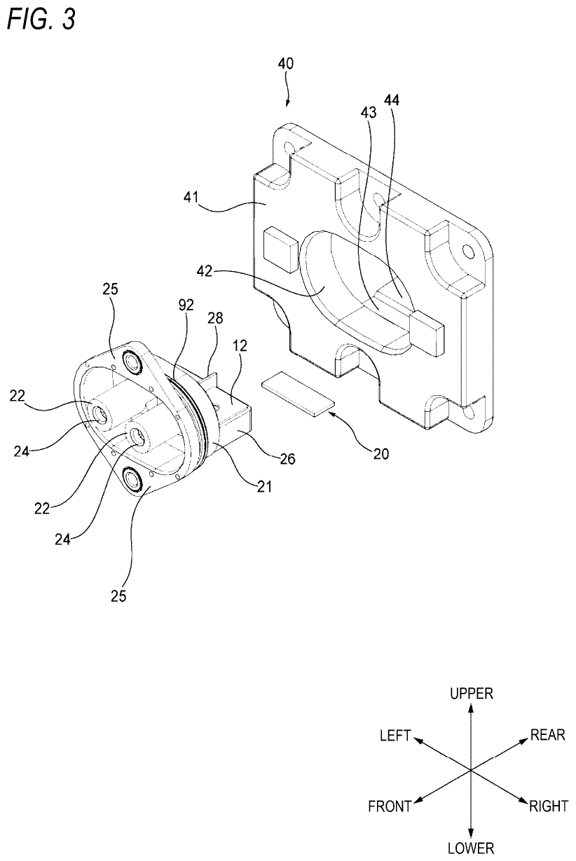

Next, the housing 20 will be described. The housing 20 is a resin molded product, and as shown in FIGS. 3 and 4, integrally includes an outer tube portion 21 that has a long hole shape elongated in the left-right direction as viewed from the front and that extends in the front-rear direction, a pair of cylindrical terminal fitting accommodation tube portions 22 that extend in the front-rear direction inside the outer tube portion 21 and that are arranged side by side in the left-right direction, and a flat plate-shaped rear end wall portion 23 that connects the rear end portions of the outer tube portion 21 and the pair of terminal fitting accommodation tube portions 22 to each other. The front end side of the outer tube portion 21 is open, and the rear end side of the outer tube portion 21 is blocked by the rear end wall portion 23. The rear end side of each terminal fitting accommodation tube portion 22 is open, and the front end side of each terminal fitting accommodation tube portion 22 communicates with the outside through the through hole 24. The tubular contact portion 11 of the terminal fitting 10 is accommodated in the terminal fitting accommodation tube portion 22. A pair of upper and lower flat plate-shaped flange portions 25 that extend outwardly on both the upper and lower sides are provided at the front end edge portion of the outer tube portion 21. A rubber packing 92 is provided on the outer peripheral surface of the outer tube portion 21 at a position adjacent to the rear side of the pair of flange portions 25. When the housing 20 is mounted on the frame member 40, the packing 92 has a function of sealing the gap between the inner peripheral surface of a penetrating hole 42 of the frame member 40 that is externally fitted onto the outer tube portion 21 and the outer peripheral surface of the outer tube portion 21.

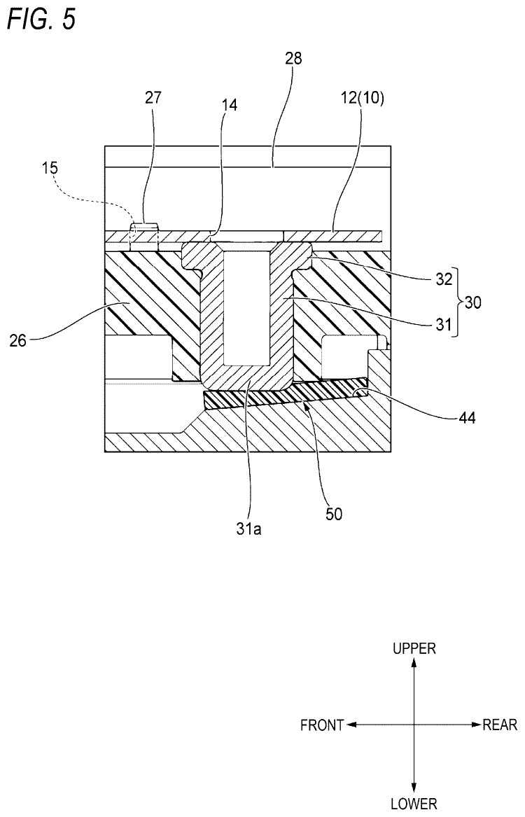

As shown in FIGS. 1, 3, and 4, the housing 20 is integrally provided with a substantially rectangular flat plate-shaped extension portion 26 that extends rearward from a part of the rear end wall portion 23 adjacent to the lower side of the rear end openings of the pair of terminal fitting accommodation tube portions 22. When the pair of left and right terminal fittings 10 are accommodated in the housing 20, the pair of left and right plate-shaped fastening portions 12 cover the upper face of the extension portion 26 (see FIGS. 1 and 4). When the pair of left and right terminal fittings 10 are accommodated in the housing 20, as shown in FIGS. 4 and 5, the nut member 30 is embedded (integrated) by insert molding in a location of the extension portion 26 where each of the pair of left and right bolt through holes 14 is formed. The nut member 30 is a member that functions to fasten and fix the terminal fitting 10 and the external terminal 81 to the housing 20. The nut member 30 is made of metal, and includes a cylindrical tubular body portion 31 that extends in the upper-lower direction, that has a lower end side blocked by a bottom wall portion 31a, and that has an open upper end side, and a flange portion 32 that extends from the opening edge portion at the upper end of the tubular body portion 31 in the radial direction of the tubular body portion 31. A female screw corresponding to the male screw of the bolt 91 is formed on the inner peripheral side face of the tubular body portion 31. A large portion of the tubular body portion 31 is embedded in the extension portion 26, and the upper end opening of the tubular body portion 31 and the flange portion 32 are exposed to the outside at the upper face of the extension portion 26. The bottom wall portion 31a (more specifically, the lower end side portion of the bottom wall portion 31a) of the tubular body portion 31 is exposed so as to slightly protrude downward from the lower end surface of the extension portion 26.

A pair of left and right locking protrusions 27 are provided on the upper face of the extension portion 26 at positions adjacent to the front sides of the pair of left and right nut members 30, corresponding to the pair of left and right locking holes 15 of the plate-shaped fastening portion 12 of each terminal fitting 10 (see FIG. 1). A plate-shaped partition wall portion 28 that protrudes upward and that extends in the front-rear direction is provided on the upper face of the extension portion 26 at a position between the pair of left and right nut members 30. The partition wall portion 28 partitions the space between the pair of left and right plate-shaped fastening portions 12 to be provided on the upper face of the extension portion 26, thereby functioning to prevent the occurrence of unintentional short circuits between the pair of left and right plate-shaped fastening portions 12.

Next, the frame member 40 will be described. As shown in FIGS. 3 and 4, the metal frame member 40 includes a substantially rectangular flat plate-shaped body portion 41 that extends in the left-right direction and the upper-lower direction. In the central portion of the body portion 41, the penetrating hole 42 that has a long hole shape elongated in the left-right direction as viewed in the front-rear direction and that penetrates the body portion 41 in the front-rear direction is provided corresponding to the outer tube portion 21 of the housing 20. The outer tube portion 21 of the housing 20 is inserted into the penetrating hole 42, so that the housing 20 is mounted on the frame member 40.

As shown in FIGS. 1, 3, and 4, the frame member 40 is integrally provided with a substantially rectangular flat plate-shaped extension portion 43 that extends rearward from a part of the body portion 41 adjacent to the lower side of the rear end opening of the penetrating hole 42. When the housing 20 is mounted on the frame member 40, the extension portion 26 of the housing 20 covers the upper face of the extension portion 43 (see FIGS. 1 and 4). When the housing 20 is mounted on the frame member 40, as shown in FIGS. 3 to 5, an installation surface 44 is provided at a location of the upper face of the extension portion 43, which faces the bottom wall portions 31a of the pair of left and right nut members 30 exposed from the lower end surface of the extension portion 26 with a small gap therebetween in the upper-lower direction. In this example, as shown in FIGS. 4 and 5, the installation surface 44 is a flat surface that extends so as to be slightly inclined with respect to the front-rear direction in an orientation in which the rear side is located higher than the front side, and that extends parallel to the left-right direction over the entire region of the extension portion 43 in the left-right direction. As will be described later, the installation surface 44 functions as a portion that sandwiches the sheet-shaped heat transfer member 50 with the bottom wall portion 31a of the nut member 30.

Next, the heat transfer member 50 will be described. The heat transfer member 50 is a member used to be sandwiched between the bottom wall portions 31a of the pair of left and right nut members 30 exposed from the lower end surface of the extension portion 26 and the installation surface 44 of the frame member 40 when the housing 20 is mounted on the frame member 40 (see FIGS. 4 and 5). In this example, as shown in FIG. 3, the heat transfer member 50 has a thin sheet shape that is elongated in the left-right direction as viewed in the upper-lower direction. The heat transfer member 50 is made of a material that has higher thermal conductivity than the resin material constituting the housing 20 and that is flexible enough to deform to fit the shape of the gap between the bottom wall portion 31a of the nut member 30 and the installation surface 44 of the frame member 40.

The heat transfer member 50 can be made of, for example, a thermally conductive resin material, a mixed material in which a resin serving as a base material is mixed with a heat transfer body having the thermal conductivity, and a mesh-shaped material made of a wire material having the thermal conductivity. The heat transfer member 50 may be formed by processing these materials into a plate shape or a tape shape. Further, if these materials are sufficiently soft under the usage environment of the heat transfer member 50, these materials may be applied to the housing 20 or the frame member 40 in a paste form.

The configurations of the members that constitute the connector unit 1 have been described above.

Next, the assembling procedure of the connector unit 1 will be described. First, the pair of left and right terminal fittings 10 are accommodated in the housing 20. Therefore, the tubular contact portion 11 of the terminal fitting 10 is inserted into each terminal fitting accommodation tube portion 22 of the housing 20 from the rear side. The plate-shaped fastening portion 12 of the terminal fitting 10 covers the upper face of the extension portion 26 of the housing 20 such that the bolt through hole 14 is located on the upper end opening of the nut member 30 and such that the locking hole 15 is locked to the locking protrusion 27 of the housing 20 (see FIGS. 1 and 4). The locking hole 15 is locked to the locking protrusion 27, so that the positional deviation of the terminal fitting 10 with respect to the housing 20 is prevented.

Next, the housing 20 is mounted on the frame member 40. Therefore, the outer tube portion 21 of the housing 20 is inserted into the penetrating hole 42 of the frame member 40 until the flange portion 25 of the housing 20 abuts against the body portion 41 of the frame member 40 in a state in which the sheet-shaped heat transfer member 50 is attached to the bottom wall portions 31a of the pair of left and right nut members 30 exposed from the lower end surface of the extension portion 26 of the housing 20 or the installation surface 44 of the extension portion 43 of the frame member 40. When the housing 20 is completely mounted on the frame member 40, the heat transfer member 50 is pressed and clamped between the bottom wall portion 31a of the nut member 30 and the installation surface 44 of the frame member 40, as shown in FIG. 5, and due to the flexibility of the heat transfer member 50, the heat transfer member 50 flexibly deforms to fit the shape of the gap between the bottom wall portion 31a of the nut member 30 and the installation surface 44 of the frame member 40. Therefore, as compared with a case in which the heat transfer member 50 does not have the flexibility, the heat transfer member 50 is in contact with both the nut member 30 and the frame member 40 with a large contact area. In other words, the heat transfer member 50 thermally connects the nut member 30 and the frame member 40. Further, as described above, since the installation surface 44 extends so as to be slightly inclined with respect to the front-rear direction in an orientation in which the rear side is located higher than the front side, as compared with a case in which the installation surface 44 extends parallel to the front-rear direction, the heat transfer member 50 is less likely to be turned over due to the frictional force received from the bottom wall portion 31a of the nut member 30 when the housing 20 is mounted on the frame member 40, and the pressing force that the heat transfer member 50 receives from the bottom wall portion 31a of the nut member 30 and the installation surface 44 increases, making it easier for the heat transfer member 50 to come into closer contact with the bottom wall portion 31a of the nut member 30 and the installation surface 44. According to the above, the assembly of the connector unit 1 is completed, and the connector unit 1 shown in FIGS. 1 and 2 is obtained.

The connector unit 1 after assembly is fitted into the counterpart connector 2 shown in FIG. 1. The housing 60 of the counterpart connector 2 includes a connector portion 61 that extends in the front-rear direction and an electric wire accommodation portion 62 that extends in the upper-lower direction, and has a substantially L shape as viewed in the left-right direction. The connector portion 61 includes an outer tube portion 63 having a shape that can be fitted into the connector portion 61 of the housing 20, and a pair of left and right terminal fitting accommodation tube portions 64 each having a shape that can be fitted into a respective one of the pair of left and right terminal fitting accommodation tube portions 22 of the housing 20. The terminal fitting (the male terminal) 71 is accommodated in each of the pair of left and right terminal fitting accommodation tube portions 64. A pair of left and right electric wires 72, one ends of which are connected to the pair of left and right terminal fittings 71, pass through the inside of the electric wire accommodation portion 62 and extend downward to the outside from the lower end opening of the electric wire accommodation portion 62.

The connector unit 1 and the counterpart connector 2 are fitted to each other such that the outer tube portion 21 is externally fitted onto the outer tube portion 63 and the terminal fitting accommodation tube portion 22 is internally inserted into the terminal fitting accommodation tube portion 64. In a state in which fitting of the connector unit 1 and the counterpart connector 2 is completed, the tubular contact portion 11 of the terminal fitting 10 in the terminal fitting accommodation tube portion 22 is electrically connected to the terminal fitting 71 in the terminal fitting accommodation tube portion 64. A packing 93 (see FIG. 1) that is provided on the outer peripheral surface of the outer tube portion 63 has a function of sealing the gap between the inner peripheral surface of the outer tube portion 21 of the housing 20 that is externally fitted onto the outer tube portion 63 and the outer peripheral surface of the outer tube portion 63.

Further, in the connector unit 1 after assembly, the external terminal 81 that is connected to the electric wire 82 is fastened and fixed to the plate-shaped fastening portions 12 of the pair of left and right terminal fittings 10 using the nut member 30 and the bolt 91 (see FIG. 4). Specifically, the bolt 91 that is inserted into the bolt through hole 81a formed in the flat plate-shaped portion of the external terminal 81 and the bolt through hole 14 of the plate-shaped fastening portion 12 in this order is screwed toward the internal space of the tubular body portion 31 of the nut member 30, so that the terminal fitting 10 and the external terminal 81 are fastened and fixed to the nut member 30 fixed to the housing 20.

In the connector unit 1, the contact point between the terminal fitting 10 and the terminal fitting 71 is located in the housing 20 in order to be insulated from the outside even though the contact point is a location where the Joule heat generated in the terminal fitting is large at the time of energization due to the large contact resistance. Therefore, it is fairly difficult to dissipate heat from the contact point between the terminal fitting 10 and the terminal fitting 71 to the outside. Further, for example, when a large current passes through the connector unit 1 in the state in which the connector unit 1 and the counterpart connector 2 are fitted to each other, the amount of generated heat also increases. In this regard, in the connector unit 1, the heat transfer member 50 is sandwiched between the bottom wall portion 31a of the nut member 30 exposed from the housing 20 and the metal frame member 40. Accordingly, the heat generated at the contact point between the terminal fitting 10 and the terminal fitting 71 at the time of energization is transferred in the order of the nut member 30, the heat transfer member 50, and the frame member 40. Since the heat transfer member 50 has the flexibility as described above, the heat transfer member 50 comes into contact with both the frame member 40 and the nut member 30 with a large contact area as compared with a case in which the heat transfer member 50 does not have the flexibility. Accordingly, in the connector unit 1, heat dissipation can be improved.

### Operation and Effect

As described above, according to the connector unit 1 in the present embodiment, the external terminal 81 and the terminal fitting 10 are fixed to the housing 20 in a state of being fastened and fixed to the nut member 30 embedded in the housing 20 and being electrically connected. Further, the heat transfer member 50 is sandwiched between the bottom wall portion 31a of the nut member 30 exposed from the housing 20 and the metal frame member 40. Accordingly, the heat generated at the contact point between the terminal fitting 10 and the terminal fitting 71 of the counterpart connector 2 at the time of energization is transferred in the order of the nut member 30, the heat transfer member 50, and the frame member 40. The heat transfer member 50 is flexible enough to deform to fit the shape of the gap between the frame member 40 and the bottom wall portion 31a of the nut member 30, and thus comes into contact with both the frame member 40 and the bottom wall portion 31a of the nut member 30 with a larger contact area as compared with the case in which the heat transfer member 50 does not have such flexibility. Further, even when an external force such as vibration is applied when the connector unit 1 is used, or even when the connector unit 1 is used for a long period of time, a state can be maintained in which the heat transfer member 50 is in contact with the frame member 40 and the bottom wall portion 31a of the nut member 30. In addition, the metal frame member 40 has a large heat capacity and high thermal conductivity, and since the frame member 40 is in contact with the outside air, the frame member 40 also has excellent heat dissipation property. Accordingly, the connector unit 1 according to the present embodiment can improve the heat dissipation property while avoiding an increase in size of the connector unit 1.

### Other Embodiments

The present disclosure is not limited to the embodiment described above and various modifications can be used within the scope of the present disclosure. For example, the present disclosure is not limited to the embodiment described above, and modifications, improvements, and the like can be appropriately made. In addition, the material, shape, size, number, arrangement position, and the like of the components in the embodiment described above are freely selected and are not limited as long as the present disclosure can be implemented.

Here, the features of the connector unit 1 according to the embodiment of the present disclosure described above are briefly summarized and listed in the following [1] to [3].
[1] A connector unit (1) including:
a terminal fitting (10);
a housing (20) configured to accommodate the terminal fitting (10);
a fixing fitting (30) embedded in the housing (20) and configured to fasten and fix the terminal fitting (10) and an external conductive component (81);
a metal frame member (40) on which the housing (20) is mounted; and
a heat transfer member (50) configured to thermally connect the frame member (40) and a part (31a) of the fixing fitting (30) exposed from the housing (20),
in which the heat transfer member (50) is sandwiched between the part (31a) of the fixing fitting (30) and the frame member (40), and is flexible enough to deform to fit a shape of a gap between the part (31a) of the fixing fitting (30) and the frame member (40).

According to the connector unit having the configuration in [1] described above, the external conductive component (for example, a round terminal and a bus bar) and the terminal fitting are fixed to the housing in a state of being fastened and fixed to the fixing fitting embedded in the housing and being electrically connected. Further, the heat transfer member is sandwiched between the part of the fixing fitting exposed from the housing and the metal frame member. Accordingly, the heat generated at the contact point between the terminal fitting and the counterpart terminal fitting, the connection location between the terminal fitting and the conductive component, and the like at the time of energization is transferred in the order of the fixing fitting, the heat transfer member, and the frame member. The heat transfer member is flexible enough to deform to fit the shape of the gap between the frame member and the part of the fixing fitting, and thus comes into contact with both the frame member and the part of the fixing fitting with a larger contact area as compared with the case in which the heat transfer member does not have such flexibility. Further, even when an external force such as vibration is applied when the connector unit is used, or even when the connector unit is used for a long period of time, a state can be maintained in which the heat transfer member is in contact with the frame member and the part of the fixing fitting. In addition, the metal frame member has a large heat capacity and high thermal conductivity, and since the frame member is in contact with the outside air, the frame member also has excellent heat dissipation property. Accordingly, the connector unit having the present configuration can improve the heat dissipation property while avoiding an increase in size of the connector unit.

The heat transfer member may be in direct contact with the frame member and the part of the fixing fitting, or indirectly in contact with the frame member and the part of the fixing fitting with an adhesive, a pressure-sensitive adhesive, or the like interposed therebetween. However, in the latter case, it is preferable that the adhesive, the pressure-sensitive adhesive, or the like also has high thermal conductivity. Further, in addition to the adhesive, the pressure-sensitive adhesive, or the like, the heat transfer member may be indirectly in contact with the frame member and the part of the fixing fitting with another member that has high thermal conductivity or the like interposed therebetween.
[2] The connector unit (1) according to [1] described above,
in which the frame member (40) has an installation surface (44) that extends in a direction intersecting a mounting direction in which the housing (20) is mounted on the frame member (40), and
in which the heat transfer member (50) is sandwiched between the part (31a) of the fixing fitting (30) and the installation surface (44).

According to the connector unit having the configuration in [2] described above, when the housing is mounted on the frame member, the heat transfer member is sandwiched between the part of the fixing fitting and the installation surface of the frame member. Accordingly, the heat transfer member is sandwiched between the part of the fixing fitting and the installation surface and comes into close contact with the part of the fixing fitting and the installation surface. Here, since the installation surface extends in the direction intersecting the mounting direction in which the housing is mounted on the frame member, as compared with a case in which the installation surface extends parallel to the mounting direction, the heat transfer member is less likely to be turned over when the housing is mounted on the frame member, and the pressing force that the heat transfer member receives from the part of the fixing fitting and the installation surface increases, making it easier for the heat transfer member to come into closer contact with the part of the fixing fitting and the installation surface. Accordingly, the heat generated at the time of energization is efficiently transmitted from the part of the fixing fitting to the frame member through the heat transfer member.
[3] The connector unit (1) according to [1] described above,
in which a material constituting the heat transfer member (50) has higher thermal conductivity than a material constituting the housing (20).

According to the connector unit having the configuration in [3] described above, the material constituting the heat transfer member has higher thermal conductivity than the material constituting the housing. Accordingly, the heat generated at the connection location between the terminal fitting and the conductive component or the like can be dissipated to the outside through the heat transfer member more efficiently than when the housing is brought into direct contact with the shield member.

1. A connector unit comprising:
a terminal fitting;
a housing configured to accommodate the terminal fitting;
a fixing fitting embedded in the housing and configured to fasten and fix the terminal fitting and an external conductive component;
a metal frame member on which the housing is mounted; and
a heat transfer member configured to thermally connect the frame member and a part of the fixing fitting exposed from the housing,
wherein the heat transfer member is sandwiched between the part of the fixing fitting and the frame member, and is flexible enough to deform to fit a shape of a gap between the part of the fixing fitting and the frame member.

2. The connector unit according to claim 1,
wherein the frame member has an installation surface that extends in a direction intersecting a mounting direction in which the housing is mounted on the frame member, and
wherein the heat transfer member is sandwiched between the part of the fixing fitting and the installation surface.

3. The connector unit according to claim 1,
wherein a material constituting the heat transfer member has higher thermal conductivity than a material constituting the housing.
